(19) United States
(12) Patent Application Publication
(10) Pub. No.: US 2021/0141967 A1
(43) Pub. Date: May 13, 2021

(54) System and Method of Imaging a Construction Plan onto a Walkable Area

(71) Applicant: Awan Capital Partners IP, LLC, Dallas, TX (US)

(72) Inventor: Daniyal Mushtaq Awan, Dallas, TX (US)

(21) Appl. No.: 17/098,244

(22) Filed: Nov. 13, 2020

Related U.S. Application Data
(60) Provisional application No. 62/934,658, filed on Nov. 13, 2019.

(51) Int. Cl. G06F 30/13; G06T 17/05; G03B 21/28; G06F 3/01

(52) U.S. Cl. CPC G06F 30/13; G06F 3/011; G03B 21/28; G06T 17/05

(57) ABSTRACT

A system and method is provided for imaging a construction plan onto a walkable area. The system includes a plurality of imaging devices, a video processing unit, and a personal computing (PC) device. The plurality of imaging devices may be any set of imaging devices capable of outputting an image. The video processing unit manages the plurality of imaging devices in order for a single image of a desired construction plan to be outputted. The PC device allows for user input to manage and control what is outputted by the plurality of imaging devices. The desired construction plan can be selected with the PC device. The video processing unit partitions the desired construction plan and assigns a plurality of plan portions to a corresponding imaging device. The corresponding imaging device then output a single image of the desired construction plan onto a walkable area.

The current application claims a priority to the U.S. Provisional Patent application Ser. No. 62/934,658 filed on Nov. 13, 2019.

### FIELD OF THE INVENTION

The present invention relates generally to virtual construction plans. More specifically, the present invention is a system and method of imaging a construction plan onto a walkable area.

### BACKGROUND OF THE INVENTION

A majority of construction developers often feel the need to be able to walk through a future project's construction plan before it is built. Once the building structure is up, change orders and alterations in the construction plan are expensive. The present invention enables users to feel and view the space they are building before building it. Thus, users will be prevented from spending time and money before realizing the need for an alteration or a refinement in the space created or built. New home-owners, architects, designers, or other similar users can use the present invention to walk through their actual designs displayed on a 1:1 scale and make changes in their plans before building them.

Making a virtual 3-D tour or other current methods to view construction plans on a 1:1 scale is expensive and time consuming so not every developer or home builder can afford them. Moreover, these current methods require special high-performance software, hardware, and a skilled designer to make them. Thus, it is an objective of the present invention to provide a system and method of imaging a construction plan onto a walkable area. The present invention requires less space, cheaper equipment, is less technical to setup, is more reliable, and is essentially a better and more intuitive experience for a client. The present invention uses the actual construction plan that is submitted to the city for permits so it is already required for construction and no additional time or money is spent to create design files for the present invention to display. Moreover, the present invention outputs an actual 1:1 scale walkable tour the user can experience, hence it allows maximum feel of the future construction spaces and dimensions.

### BRIEF DESCRIPTION OF THE DRAWINGS

FIG. 1 is a diagram illustrating the system of the present invention.

FIG. 2 is a flowchart illustrating the overall process for the method of the present invention.

FIG. 3 is a flowchart illustrating the subprocess of using light-emitting diode (LED) cabinets as the plurality of imaging devices.

FIG. 4 is a flowchart illustrating the subprocess of plumbing the LED cabinets with a plurality of leveling trusses.

FIG. 5 is a flowchart illustrating the subprocess of using liquid crystal display (LCD) devices as the plurality of imaging devices.

FIG. 6 is a flowchart illustrating the subprocess of using surface mounted diode (SMD) devices as the plurality of imaging devices.

FIG. 7 is a flowchart illustrating the subprocess of using projectors as the plurality of imaging devices.

FIG. 8 is a flowchart illustrating the subprocess of mounting the projectors to a plurality of elevation mounts.

FIG. 9 is a flowchart illustrating the subprocess of scaling the desired construction plan as a life-size rendition.

FIG. 10 is a flowchart illustrating the subprocess of a pan and/or zoom feature.

FIG. 11 is a flowchart illustrating the subprocess of further detailing the desired construction plan with a plurality of physical mockup objects.

FIG. 12 is a flowchart illustrating the subprocess of further detailing the desired construction plan with a plurality of plan overlays.

FIG. 13 is a flowchart illustrating the subprocess of editing the desired construction plan.

### DETAIL DESCRIPTIONS OF THE INVENTION

All illustrations of the drawings are for the purpose of describing selected versions of the present invention and are not intended to limit the scope of the present invention.

In reference to FIGS. 1 through 13, the present invention is a system and method of imaging a construction plan onto a walkable area. In more detail, the present invention is a system and method that can output a single image of various types of construction plans such as, but not limited to, a site plan, a dimensional control plan, a furniture layout plan, a civil engineering design plan, an elevation plan, an electrical plan, an heating-vacuum-and-air-conditioning (HVAC) plan, a mechanical plan, or a plumbing plan onto an area where a user can traverse while viewing the construction plan. With reference to FIG. 1, the system of the present invention includes a plurality of imaging devices, a video processing unit, and a personal computing (PC) device (Step A). The plurality of imaging devices is associated with a walkable area. The plurality of imaging devices may be a set of imaging devices such as, but not limited to, liquid crystal display (LCD) screen assemblies, light-emitting diode (LED) module assemblies, surface mount derive (SMD) screen assemblies, or projectors. The video processing unit manages the plurality of imaging devices in order to allow a single image to be outputted with the plurality of imaging devices. The PC device may be any computing device such as, but not limited to, a desktop computer, a notebook computer, or a mobile device. The PC device allows for user input to control and manage what is outputted with the plurality of imaging devices. The walkable area is a designated space which an individual may walk upon when viewing the outputted image from the plurality of imaging devices.

The method of the present invention follows an overall process that allows provides an imaging of a construction plan onto a walkable area. With reference to FIG. 2, the PC device prompts a user to designate a desired floor plan (Step B). The desired floor plan may be any floor plan that is stored on the PC device. The desired floor plan is relayed from the PC device to the video processing unit, if the desired floor plan is designated with the PC device (Step C). Thus, the video processing unit is given instructions to manage the desired floor plan. The video processing unit then partitions the desired floor plan into a plurality of plan portions (Step D). The plurality of plan portions is a set of image pieces that make up the desired floor plan. The video processing unit assigns each plan portion to the corresponding imaging device (Step E). The corresponding imaging device is from the plurality of imaging devices. Thus, each imaging device is provided instructions on which image piece to output. Finally, the corresponding imaging device simultaneously outputs each plan portion as a single image on the walkable area (Step F). Thus, an individual may view a floor plan while traversing across the walkable area.

As mentioned previously, the plurality of imaging devices may be any type of imaging device. In one embodiment and with reference to FIG. 3, the plurality of imaging devices may be a plurality of light-emitting diode (LED) cabinets. The plurality of LED cabinets is a set of LED display panel assemblies. Each of the plurality of LED cabinets comprises a plurality of LED modules and a receiver card, and the plurality of LED modules is coincident with the walkable area. Each plan portion is relayed from the video processing unit to the receiver card of the corresponding imaging device after Step E. Thus, each of the plurality of LED cabinets is instructed to display a specific piece of the construction plan. The plurality of LED modules of the corresponding imaging device then displays each plan portion during Step F. Thus, a single image of the construction plan is displayed with the plurality of LED cabinets.

In order to continuously stabilize the walkable area as a user traverses across the walkable area and with reference to FIG. 4, the following subprocess is executed. The plurality of LED cabinets is provided as a display assembly. In more detail, the display assembly is a frame that borders and houses the plurality of LED modules. The display assembly includes a top assembly face and a bottom assembly face. The plurality of LED modules for each LED cabinet is positioned adjacent to the top assembly face, and a plurality of leveling trusses is mounted across the bottom assembly face. The plurality of leveling trusses is a set of mechanical stabilizers that continuously keeps the walkable area at 180 degrees. The display assembly is plumbed with the plurality of leveling trusses. Thus, the walkable area is continuously kept at 180 degrees in order to prevent a user from stumbling when walking across the walkable area.

In an alternative embodiment and with reference to FIG. 5, the plurality of imaging devices may be a plurality of liquid crystal display (LCD) devices. The plurality of LCD devices is a set of LCD display panel assemblies. Each of the plurality of LCD devices comprises a plurality of LCD modules and a receiver card, and the plurality of LCD modules is coincident with the walkable area. Each plan portion is relayed from the video processing unit to the receiver card of the corresponding imaging device after Step E. Thus, each of the plurality of LCD devices is instructed to display a specific piece of the construction plan. The plurality of LCD modules of the corresponding imaging device then displays each plan portion during Step F. Thus, a single image of the construction plan is displayed with the plurality of LCD devices. Similar to the plurality of LED cabinets, the plurality of leveling trusses may be used to plumb the plurality of LCD devices.

As another alternative and with reference to FIG. 6, the plurality of imaging devices may be a plurality of surface mounted diode (SMD) devices. The plurality of SMD devices is a set of SMD display panel assemblies. Each of the plurality of SMD devices comprises a plurality of SMD modules and a receiver card, and the plurality of SMD modules is coincident with the walkable area. Each plan portion is relayed from the video processing unit to the receiver card of the corresponding imaging device after Step E. Thus, each of the plurality of SMD devices is instructed to display a specific piece of the construction plan. The plurality of SMD modules of the corresponding imaging device then displays each plan portion during Step F. Thus, a single image of the construction plan is displayed with the plurality of SMD devices. Similar to the plurality of LED cabinets, the plurality of leveling trusses may be used to plumb the plurality of LCD devices.

As another alternative and with reference to FIG. 7, the plurality of imaging devices may be a plurality of projectors. Each plan portion is relayed from the video processing unit to the corresponding imaging device after Step E. Thus, each projector is instructed to display a specific piece of the construction plan. The corresponding imaging device then projects each plan portion during Step F. Thus, a single image of the construction plan is projected with the plurality of projectors. In order for the plurality of projects to effectively project the construction plan onto the walkable area and with reference to FIG. 8, each projector is mounted onto at least one elevation mount. Each projector is positioned offset from the walkable area by the elevation mount, and each projector is oriented towards the walkable area by the elevation mount. The elevation mount is preferably a u-shaped structure that is positioned over the walkable area and can receive and secure the projectors.

In order to output the single image as a 1:1 scaled design and with reference to FIG. 9, the following subprocess is executed. The video processing unit scales the desired construction plan to a life-size rendition during Step D. The life-size rendition is a 1:1 scaled version of the desired construction plan. The plurality of imaging devices outputs the life-size rendition as the single image of the desired construction plan on the walkable area during Step F. Thus, the single image is outputted as a 1:1 scaled design.

In order to allow panning or zooming of the single image and with reference to FIG. 10, the following subprocess is executed. The PC device prompts to enter a pan and/or zoom adjustment for the single image after Step F. The pan and/or zoom adjustment is an input that allows a user to pan out from or zoom into the single image. The plurality of imaging devices applies the pan and/or zoom adjustment to the single image, if the pan and/or zoom adjustment is entered by the PC device. Thus, a user can better view a specified section of the single image.

In order to further detail the construction plan with physical mockup objects and with reference to FIG. 11, the following subprocess is executed. A plurality of physical mockup objects is provided, and the single image includes a plurality of image sections. The plurality of image sections is a set of specific pieces of the single image. The plurality of physical mockup objects may be any type of mockup object such as, but not limited to, mockup furniture, mockup walls, mockup stairs, or mockup vehicles. Each physical mockup object is placed onto a desired image section after Step F. The desired image section is from the plurality of image sections. Thus, the construction plan is further detailed with mockup objects.

Alternatively and with reference to FIG. 12, the construction plan can be further detailed with the use of digital overlays. A plurality of plan overlays is provided. The plurality of plan overlays may any type of digital overlay such as, but not limited to, a color-coding overlay, a texture overlay, a picture overlay, a furniture layout overlay, a mechanical, electrical, and plumbing (MEP) layout overlay, a photometric layout overlay, or combinations thereof. The PC device prompts to select at least one desired overlay after Step F. The desired overlay is from the plurality of plan overlays. Thus, a user is given the option to choose an overlay from the plurality of plan overlays. The desired overlay is relayed from the PC device to the video processing unit, if the desired overlay is selected from the plurality of plan overlays with the PC device. Thus, the video processing unit can manage the desired overlay. The video processing unit then partitions the desired overlay into a plurality of overlay portions. The plurality of overlay portions is a set of pieces that make up the desired overlay. The video processing unit assigns each overlay portion to a corresponding image section. The corresponding image section is from the plurality of image sections. This step allows the desired overlay to be properly displayed onto the single image. Finally, the plurality of imaging devices graphically applies each overlay portion onto the corresponding image section. Thus, the construction plan is further detailed with the desired overlay.

In order for the construction plan to be edited in real-time and with reference to FIG. 13, the following subprocess is executed. The PC device prompts to enter at least one image edit for the single image after Step F. The image edit may be any type of edit such as, but not limited to, a change in the specifications of the construction plan, an edit to hide unnecessary details, or redrawing of the construction plans. The image edit is relayed from PC device, through the video processing unit, and to the plurality of imaging devices, if the image edit is entered with the PC device. Thus, the plurality of imaging devices receives instructions for the image edit. Finally, the plurality of imaging devices graphically applies the image edit for the single image. Thus, the construction plan is edited in real-time.

Although the invention has been explained in relation to its preferred embodiment, it is to be understood that many other possible modifications and variations can be made without departing from the spirit and scope of the invention as hereinafter claimed.

What is claimed is:

1. A method of imaging a construction plan onto a walkable area, the method comprises the steps of:
(A) providing a plurality of imaging devices, a video processing unit, and a personal computing (PC) device, wherein the plurality of imaging devices is associated with a walkable area;
(B) prompting to designate a desired construction plan with the PC device;
(C) relaying the desired construction plan from the PC device to the video processing unit, if the desired construction plan is designated with the PC device;
(D) partitioning the desired construction plan into a plurality of plan portions with the video processing unit;
(E) assigning each plan portion to a corresponding imaging device with the video processing unit, wherein the corresponding imaging device is from the plurality of imaging devices; and
(F) simultaneously outputting each plan portion as a single image on the walkable area with the corresponding imaging device.

2. The method of imaging a construction plan onto a walkable area, the method as claimed in claim 1 comprises the steps of:
providing the plurality of imaging devices as a plurality of light-emitting diode (LED) cabinets, wherein each of the plurality of LED cabinets comprises a plurality of LED modules and a receiver, and wherein the plurality of LED modules is coincident with the walkable area;
relaying each plan portion from the video processing unit to the receiver card of the corresponding imaging device after step (E); and
displaying each plan portion with the plurality of LED modules of the corresponding imaging device during step (F).

3. The method of imaging a construction plan onto a walkable area, the method as claimed in claim 2 comprises the steps of:
providing the plurality of LED cabinets as a display assembly, wherein the display assembly includes a top assembly face and a bottom assembly face, and wherein the plurality of LED modules for each LED cabinet is positioned adjacent to the top assembly face, and wherein a plurality of leveling trusses is mounted across the bottom assembly face; and
plumbing the display assembly with the plurality of leveling trusses.

4. The method of imaging a construction plan onto a walkable area, the method as claimed in claim 1 comprises the steps of:
providing the plurality of imaging devices as a plurality of liquid crystal display (LCD) devices, wherein each of the plurality of LCD devices comprises a plurality of LCD modules and a receiver, and wherein the plurality of LCD modules is coincident with the walkable area;
relaying each plan portion from the video processing unit to the receiver card of the corresponding imaging device after step (E); and
displaying each plan portion with the plurality of LCD modules of the corresponding imaging device during step (F).

5. The method of imaging a construction plan onto a walkable area, the method as claimed in claim 1 comprises the steps of:
providing the plurality of imaging devices as a plurality of surface mounted diode (SMD) devices, wherein each of the plurality of SMD devices comprises a plurality of SMD modules and a receiver, and wherein the plurality of SMD modules is coincident with the walkable area;
relaying each plan portion from the video processing unit to the receiver card of the corresponding imaging device after step (E); and
displaying each plan portion with the plurality of SMD modules of the corresponding imaging device during step (F).

6. The method of imaging a construction plan onto a walkable area, the method as claimed in claim 1 comprises the steps of:
providing the plurality of imaging devices as a plurality of projectors;
relaying each plan portion from the video processing unit to the corresponding imaging device after step (E); and
projecting each plan portion onto the walkable area with the corresponding imaging device during step (F).

7. The method of imaging a construction plan onto a walkable area, the method as claimed in claim 6, wherein each projector is mounted onto at least one elevation mount, and wherein each projector is positioned offset from the walkable area by the elevation mount, and wherein each projector is oriented towards the walkable area by the elevation mount.

8. The method of imaging a construction plan onto a walkable area, the method as claimed in claim 1 comprises the steps of:
scaling the desired construction plan to a life-size rendition with the video processing unit during step (D); and
outputting the life-size rendition as the single image of the desired construction plan on the walkable area with the plurality of imaging devices during step (F).

9. The method of imaging a construction plan onto a walkable area, the method as claimed in claim 1 comprises the steps of:
prompting to enter a pan and/or zoom adjustment for the single image with the PC device after step (F); and
applying the pan and/or zoom adjustment to the single image with the plurality of imaging devices, if the pan and/or zoom adjustment is entered by the PC device.

10. The method of imaging a construction plan onto a walkable area, the method as claimed in claim 1 comprises the steps of:
providing a plurality of physical mockup objects, wherein the single image includes a plurality of image sections; and
placing each physical mockup object onto a desired image section after step (F), wherein the desired image section is from the plurality of image sections.

11. The method of imaging a construction plan onto a walkable area, the method as claimed in claim 1 comprises the steps of:
providing a plurality of plan overlays, wherein the single image includes a plurality of image sections;
prompting to select at least one desired overlay with the PC device after step (F), wherein the desired overlay is from the plurality of plan overlays;
relaying the desired overlay from the PC device to the video processing unit, if the desired overlay is selected from the plurality of plan overlays with the PC device;
partitioning the desired overlay into a plurality of overlay portions with the video processing unit;
assigning each overlay portion to a corresponding image section with the video processing unit, wherein the corresponding image section is from the plurality of image sections; and
graphically applying each overlay portion onto the corresponding image section with the plurality of imaging devices.

12. The method of imaging a construction plan onto a walkable area, the method as claimed in claim 1 comprises the steps of:
prompting to enter at least one image edit for the single image with the PC device after step (F);
relaying the image edit from the PC device, through the video processing unit, and to the plurality of imaging devices, if the image edit is entered with the PC device; and
graphically applying the image edit to the single image with the plurality of imaging devices.
